(19) United States
(12) Patent Application Publication
(10) Pub. No.: US 2003/0162372 A1
(43) Pub. Date: Aug. 28, 2003

(54) Method and apparatus for forming an oxide layer

(76) Inventor: Woo Sik Yoo, Palo Alto, CA (US)

Correspondence Address: MacPherson Kwok Chen & Heid LLP, 2402 Michelson Drive, Suite 210, Irvine, CA, 92612, US

(21) Appl. No.: 10/085,498

(22) Filed: Feb. 26, 2002

(51) Int. Cl. H01L 21/20

(52) U.S. Cl. 438/484

(57) ABSTRACT

A steam oxidation process which provides uniform coverage of oxygen radicals across a surface of a substrate to enhance the oxidation rate and form a uniform layer of SiO₂. The steam oxidation process provides the heat and oxygen radicals for SiO₂ formation through the combustion of a process flame. The process flame can be fueled by a combination of H₂ and O₂ process gases. The process flame can include a plurality of process flames directed substantially perpendicular to the target substrate to provide uniform heating of the substrate and a uniform deposition of oxygen radicals across the surface of the substrate to enhance the formation of an oxidation layer.

### BACKGROUND

1. Field of Invention

This invention is related to a method, and apparatus for forming silicon dioxide on a substrate.

2. Related Art

In the manufacturing of planar semiconductor devices, the entire surface of a semiconductor substrate can be layered with an insulating or masking layer. The masking layer is normally a layer of silicon dioxide (SiO₂). Typically, the masking SiO₂ layer is thermally grown by oxidation of silicon (hereinafter “thermal oxidation”).

Some thermal oxidation processes have been developed for batch processing of semiconductor substrates. For example, in thermal oxidation processes for oxide formation between 200 Å and 20 μm (i.e. “thick oxide”), a semiconductor substrate, such as a silicon (Si) wafer, is subjected to a high temperature at a high pressure for a prolonged duration of time. During the process Si atoms from the body of the silicon wafer diffuse out of the silicon wafer and react with oxygen at the surface of the wafer. Also, oxygen atoms diffuse into the body of the silicon wafer and react with Si atoms at the wafer and oxygen interface. Once the Si atoms react with oxygen, a layer of SiO₂ is formed. The layer continues to grow as Si atoms reach the surface of the growing SiO₂ layer and react and as oxygen diffuses through the SiO₂ layer to react with the silicon wafer. Normally, this type of thermal oxidation process can require pressures up to 25 atms and temperatures, above 900° C., usually from 1100° C. to 1200° C.

Unfortunately, as the oxide layer grows, the thermal oxidation process, which requires exposure of Si atoms to oxygen with which the Si atoms can react, becomes limited by the time it takes for Si atoms to diffuse through the growing SiO₂ layer. Thus, thermally grown oxides using this process are formed at a very low rate and therefore require long periods of time to develop, thereby making such a process uneconomical for semiconductor device manufacture. The high-pressure operation also requires a heavily equipped system, which can also be cost ineffective.

Other processes have been developed, which use single-wafer RTP technology, to provide critical, transistor-level oxide films that were previously formed using batch processes. For example, wet oxidation processes, also known as steam oxidation processes, use steam as the process reactant, to provide rapid growth rates through the enhanced oxidation rate of steam compared to oxygen. One such process is a wet oxidation process known as In-Situ Steam Generation (ISSG) oxidation, which is an internal pyrogenic steam oxidation process. The ISSG process provides a method of growing ultra-thin gate oxides of less than 25 Å (i.e. “ultra-thin oxides”). Also, ISSG oxides offer unique material properties such as improved corner rounding and reduced stress for shallow trench isolation (STI) applications.

FIG. 6 is a simplified side-view of a typical ISSG process chamber 700. ISSG process chamber 700 is configured to support a wafer 702 for processing. A premixed process gas, such as a mixture of low-pressure oxygen (O₂) and hydrogen (H₂) is supplied to chamber 710 through inlet 704. The process gas travels across, parallel to wafer 702. Wafer 702 is heated to temperatures of between about 1000° C. and 1050° C. from an external heat source, such as a heater-lamp 707 that heats wafer 702 through window 708 positioned directly opposed to the surface of wafer 702. The heated wafer initiates low-pressure combustion of the premixed O₂ and H₂, which forms steam and oxygen radicals (O*) to enhance the oxidation rate. The process gas is exhausted through outlet 706 to a vacuum pump.

Unfortunately, because the premixed process gas is made to flow parallel to the surface of wafer 702, from inlet 704 to outlet 706, the oxygen radicals must travel a relatively large distance across wafer 702. The reaction with Si at the surface of wafer 702 begins as soon as contact is made. Thus, the oxygen radicals may not uniformly reside both in concentration and time over the entire wafer 702 before the reaction begins on the wafer surface. Accordingly, a non-uniform SiO₂ formation can occur.

### SUMMARY

The present invention includes a method and apparatus for forming an oxide layer on a substrate. In one aspect of the invention, the method and apparatus provide a pyrogenic, steam oxidation process that provides uniform coverage of an oxidation layer across a surface of a substrate. Steam is created in the process to enhance the oxidation rate to form the substantially uniform oxidation layer.

In accordance with the present invention, the steam oxidation process provides uniform coverage of oxygen radicals across a surface of the substrate, such as a silicon (Si) wafer, quartz rod and the like, to enhance the oxidation rate and form a uniform layer of SiO₂. In this aspect of the present invention, the steam oxidation process provides the heat and oxygen radicals for SiO₂ formation through the combustion of a process flame. The process flame is fueled in one example, by a combination of H₂ and O₂ process gases. The process flame can include a plurality of process flames directed substantially perpendicular to the target substrate to provide uniform heating of the substrate and a uniform deposition of oxygen radicals across the surface of the substrate. Alternatively, as described below, in addition to the heat supplied by the process flame, the wafer can be heated with heat supplied using a heater assembly.

Since the process flames are directed perpendicular to the surface of the substrate, the process window is widened. Advantageously, the perpendicularly arranged process flames provide greater control of atomic oxygen concentration, atomic oxygen concentration uniformity and atomic oxygen residence time over the surface of the substrate. For example, in accordance with the present invention oxygen radicals are not required to travel the relatively large distance across the surface of the substrate, which is typical in processes using O₂ and H₂ gas distribution substantially parallel to the wafer surface, as shown in FIG. 6. The amount of water vapor and the vapor pressure can be more readily controlled as well.

In accordance with another aspect of the present invention, an oxide layer can be formed on a substrate by applying a coating of a coating material, such as spin-on glass (SOG) or other similar type of coating material. The substrate and coating material are baked at a first process temperature for a first time duration to cause the coating material to outgas and form a layer of SiO₂. The newly created layer of SiO₂ is then heated to a second process temperature for a second time duration to cause the SiO₂ layer to cure.

Advantageously, the different aspects of the present invention, as detailed below, decrease the process times for thermal oxidation, which makes the process cost and time efficient for manufacturing. Moreover, the processes of the present invention can occur at or about atmospheric pressure, which removes the need for heavily equipped, high-pressure systems.

These and other features and advantages of the present invention will be more readily apparent from the detailed description of the preferred embodiments set forth below taken in conjunction with the accompanying drawings.

### BRIEF DESCRIPTION OF THE DRAWINGS

FIGS. 1A and 1B are simplified cross-sectional illustrations of a reactor in accordance with embodiments of the present invention;

FIG. 1C is a simplified illustration of a process chamber in accordance with an embodiment of the present invention;

FIG. 1D is a simplified illustration of a process chamber in accordance with an embodiment of the present invention;

FIG. 2A is a simplified illustration of an embodiment of a burner assembly in accordance with an embodiment of the present invention;

FIGS. 2B, 2C and 2D are simplified illustrations of alternative embodiments of the burner assembly of FIG. 2A;

FIG. 2E is a simplified illustration of a process flame directed perpendicular to a substrate;

FIG. 3 is a graphical representation of the relationship of O₂ and H₂ in the rapid thermal steam oxidation process using hydrogen/oxygen flames in accordance with the present invention;

FIG. 4 is a flow diagram describing a process for growing an oxide layer on a substrate in accordance with the present invention;

FIG. 5 is a simplified cross sectional illustration of a coated wafer; and

FIG. 6 is a simplified illustration of a typical ISSG reactor.

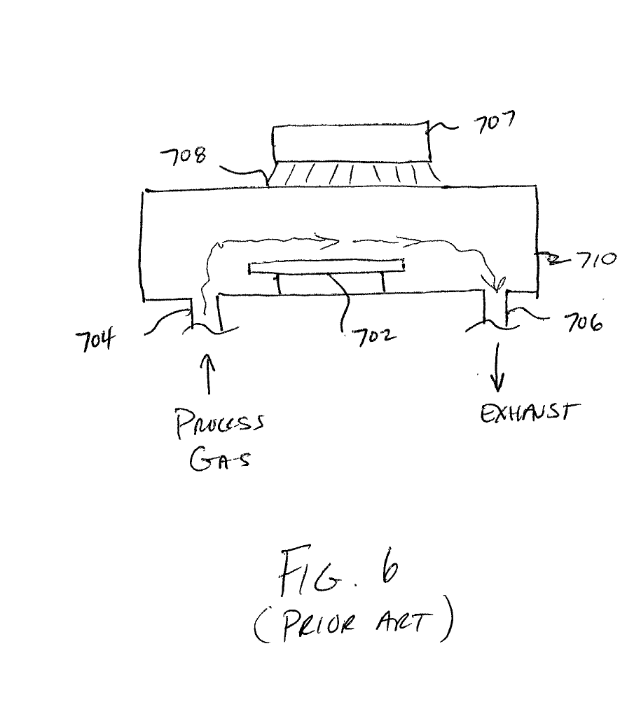

### DETAILED DESCRIPTION

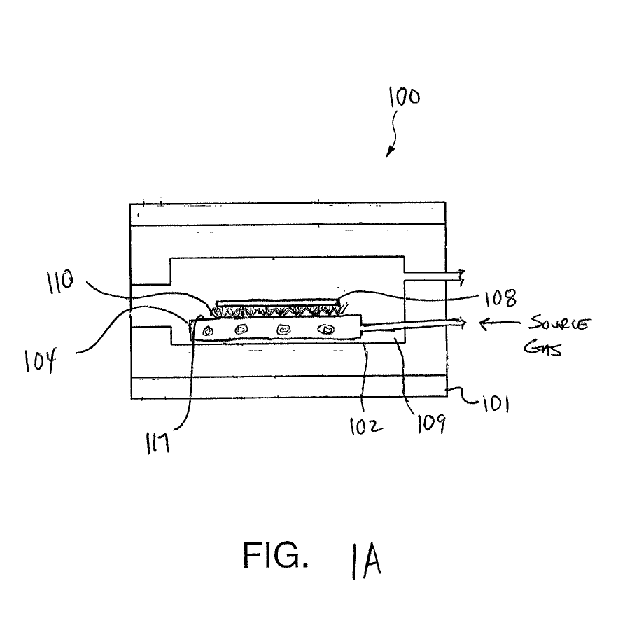

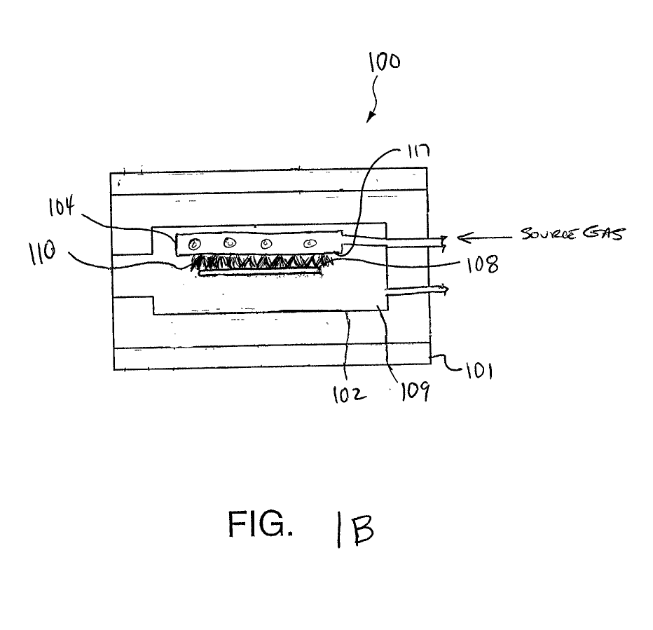

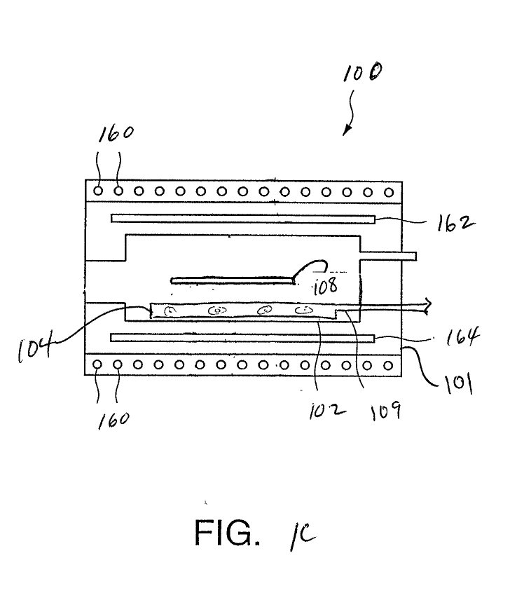

FIGS. 1A and 1B are simplified illustrations of a processing system 100 in accordance with an embodiment of the present invention. Processing system 100 includes a reactor 101 having a process chamber 102 that defines an interior cavity 109. Reactor 101 also includes a burner assembly 104 disposed in cavity 109, such that a first surface 117 of burner assembly 104 can be positioned proximate with and adjacent to wafer 108. As shown in FIGS. 1A and 1B, burner assembly 104 can be disposed either above wafer 108 or below wafer 108. Alternatively, two burner assemblies 104 can be disposed above and below wafer 108.

In accordance with an embodiment of the present invention, reactor 101 may be a hot-walled RTP reactor, such as is used in thermal anneals. In other embodiments, reactor 101 maybe the type of reactor used for dopant diffusion, thermal oxidation, nitridation, chemical vapor deposition, and/or similar processes.

Process chamber 102 may be made of quartz or other suitable material, such as silicon carbide or Al₂O₃. To conduct a process, process chamber 102 should be capable of being pressurized. Typically, process chamber 102 can accommodate internal pressures of about 0.001 Torr (about 0.13 Pa) to about 1000 Torr (about 133 kPa), preferably between about 0.1 Torr (13 Pa) and about 760 Torr (about 101 kPa).

FIGS. 1C and 1D are simplified cross-sectional illustrations of an embodiment of reactor 101 in accordance with embodiments of the present invention.

In one embodiment (FIG. 1C), a plurality of heating elements 160 surround process chamber 102. Resistive heating elements 160 may be disposed in parallel across process chamber 102, such that each element 160 is in relative close proximity to each other element 160. For example, each resistive heating element 160 may be spaced between about 5 mm and 50 mm apart; preferably between about 10 mm and 20 mm apart. Accordingly, the close spacing of heating elements 160 provides for an even heating temperature distribution across the wafer positioned in cavity 109. Heating elements 160 provide for the pre-heating of wafer 108 prior to processing. Heating elements 160 also provide the capability to increase the temperature of wafer 108 and process chamber 102 during processing beyond the temperature provided by burner assembly 104.

In one embodiment, reactor 100 includes heat-diffusing members 162 and 164, which are positioned proximate to and typically overlay heating elements 160. Heat diffusing members 162 and 164 absorb the thermal energy output from heating elements 160 and dissipate the heat evenly within process chamber 102. Heat diffusing members 162 and 164 may be any suitable heat diffusing material that has a sufficiently high thermal conductivity, preferably Silicon Carbide, Al₂O₃, graphite, SiC coated graphite and the like.

In an alternative embodiment (FIG. 1D), the plurality of heating elements 160 can be replaced with a plurality of burners 622 capable of providing a flame torch 624. Burners 622 can be supplied with any suitable flammable gas, such as natural gas, to create flame torch 624. The plurality of burners 622 can be configured to surround process chamber 102 to provide an even heating temperature distribution across wafer 108 positioned in cavity 109.

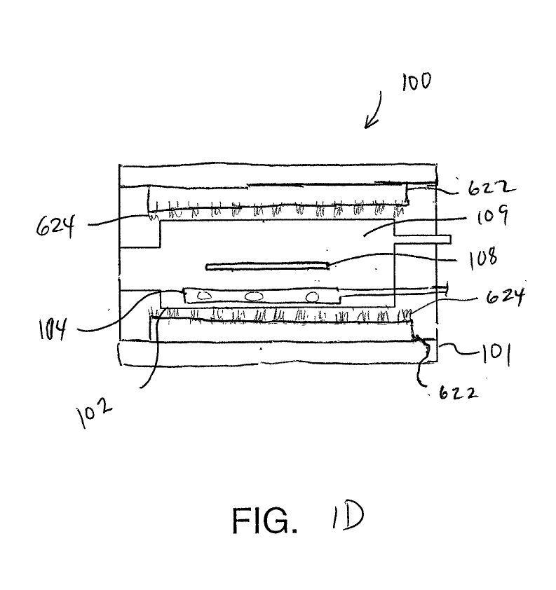

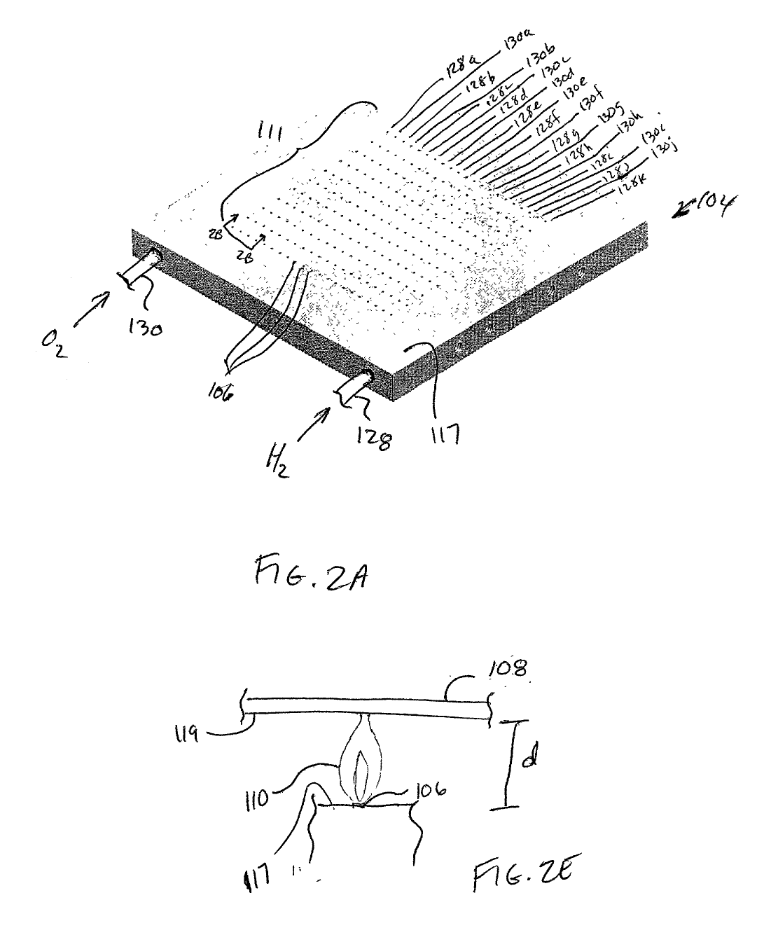

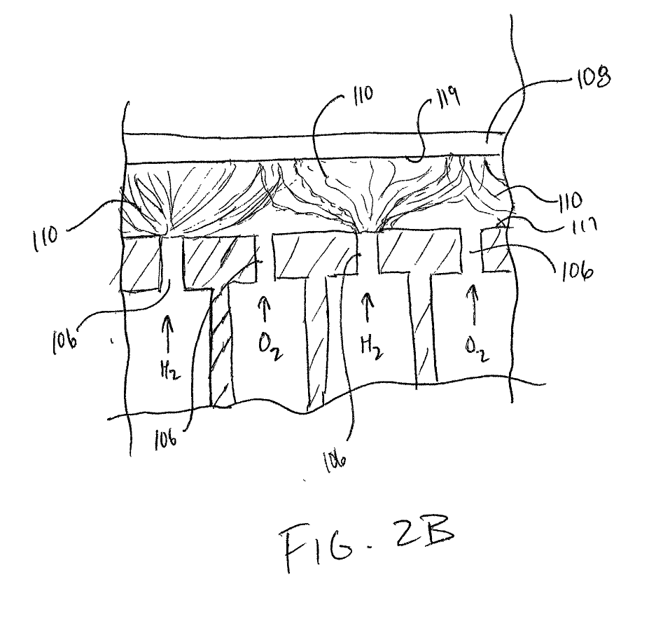

FIGS. 2A and 2B are simplified illustrations of an embodiment of burner assembly 104, in accordance with the present invention. Burner assembly 104, generally includes a plurality of individual burners or nozzles 106. Nozzles 106 are arranged on first surface 117 such that a single surface of wafer 108 positioned proximate to first surface 117 can be made to communicate with flames 110 (FIG. 2B) emanating from each nozzle 106.

In one embodiment, each nozzle 106 is aligned in a row and column to form an array 111 of nozzles 106. Nozzles 106 can be spaced in any suitable arrangement. For example, array 111 of nozzles 106 can be about 100 mm by 100 mm with a space between rows and columns of about 10 mm. Each nozzle 106 can have an opening with a diameter of between about 1 mm and 10 mm.

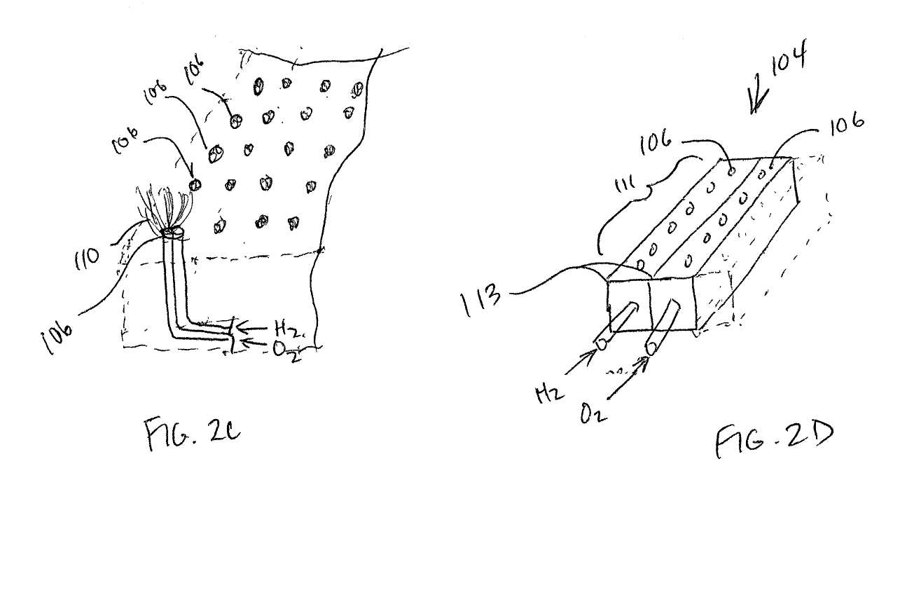

FIG. 2B provides a simplified cross-sectional view of a portion of burner assembly 104 in accordance with one embodiment. In this embodiment, H₂ and O₂ are provided to nozzles 106 in alternating rows of nozzle array 111. In this embodiment, each nozzle can be supplied individually with an ultra-high purity hydrogen or oxygen. The O₂ and H₂ combine to provide the fuel source for process flames 110. The ratios of O₂/H₂ provided allows for control of process flames 110, and thus, control of the desired reaction occurring at the surface of wafer 108 and temperature uniformity over wafer 108. FIG. 3 is a pictorial representation of the effect of the ratio between O₂/H₂ on the creation of flames 110. In one embodiment, the ratio of O₂/H₂ can range from about 0.1 to about 10.

As shown in FIGS. 2B and 2E, as H₂ gas exits nozzle 106, process flames 110 are created. Oxygen is provided to aid in the combustion and the creation of H₂O vapor and oxygen radicals. FIG. 2E illustrates a process flame 110 directed perpendicular to surface 119 of wafer 108 in accordance with the present invention. The proximity of surface 119 to process flames 110 can be adjusted to a preselected distance d to vary the intensity of process flames 110 on the wafer surface. For example, distance d can be adjusted from between about 1 mm and about 50 mm.

Process flames 110 are directed perpendicularly at a surface 119 of wafer 108, to contact and heat wafer 108 and allow steam generated in process flames 110 to contact at least the portion of surface 119 which the flame contacts. In this manner, the steam and other reactants can be concentrated and made to reside an appropriate time over the surface to provide uniform oxidation.

In an alternative embodiment, each nozzle 106 can include two outlets as shown in FIG. 2C. In this configuration, one outlet supplies H₂ and the other supplies O₂. In yet another alternative arrangement shown in FIG. 2D, burner assembly 104 can include a plurality of individual burners 113 coupled together to form burner assembly 104. Each burner 113 can be separately supplied with either H₂ or O₂ as desired. In this embodiment, the oxygen supplied burners 113 can alternate with the hydrogen supplied burners, such that an array 111 of nozzles 106 is formed which resembles the embodiment of FIG. 2B.

In most embodiments, burner assembly 104 can be made of an appropriate metal material, such as steel, steel alloys, Al, Al alloys and quartz.

Referring now to FIGS. 1A, 1B, 2A and 2B in one operational embodiment, after wafer 108 has been positioned into internal cavity 109 of process chamber 102 and readied for processing, burner assembly 104 is supplied with an ultra high purity hydrogen through inlet 128. In this embodiment, each nozzle 106 in rows 128a-128k is supplied with the hydrogen. Similarly, oxygen is supplied through inlet 130 to each nozzle 106 in rows 130a-130j.

The flame oxidation process of the present invention begins by igniting the hydrogen, using a conventional igniter, within the oxygenated environment. In this process, heat, oxygen radicals and a dilute concentration of steam are generated through the combustion of the ultra high purity hydrogen and oxygen. Since each flame 110 is directed perpendicular to surface 119 of wafer 108, the generation of steam occurs at wafer surface 119. In addition, the oxygen radicals are uniformly concentrated and their residence time at surface 119 of wafer 108 is increased. The steam is used as the process reactant to enhance the oxidation rate at surface 119 of wafer 108.

The thickness of the oxide layer can depend on the length of time surface 119 of wafer 108 is exposed to process flames 110, the pressure of process chamber 102 and the temperature of wafer 108. In one example, by controlling these parameters, the thickness of the oxide layer can be formed from between about 10 Å and 20 μm.

In one embodiment, dopant addition can be combined with the flame oxidation process. The dopant addition can be done to modulate the refractive index of the oxidation layer. For example, various dopants, such as B₂H₆, AsH₃, PH₃ and NH₃ or GeCl₄ and other rare earth elements can be added to either of the H₂ and O₂ supply lines. Alternatively, the dopants can be supplied to process chamber 102 using an alternative inlet.

In one embodiment, an external source of Si can be provided to process flames 110. For example, SiCl₄, SiH₄, Si₂H₆ and the like can be added to the O₂ and H₂ supply lines or otherwise added to process flames 110. In this embodiment, for example, by adding SiCl₄ to process flames 110, the combustion by-products can include heat, H₂O vapor, HCl and SiO₂. The external supply of Si reduces the consumption of the Si wafer, which may otherwise occur during the oxidation process. The SiO₂ can be formed in the flame and deposited on the wafer surface or can be formed directly on the wafer surface.

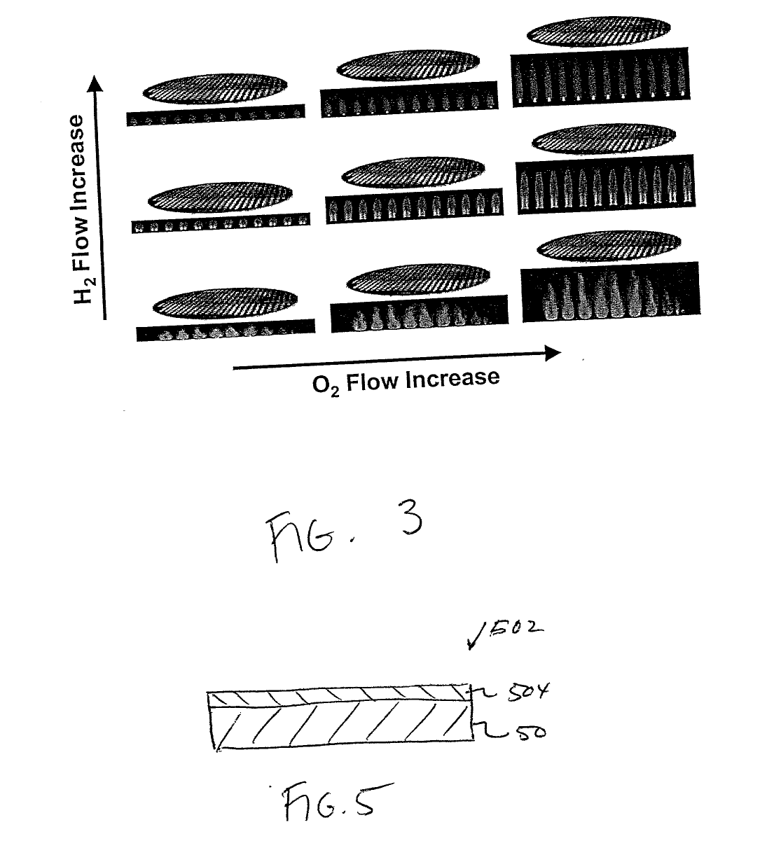

FIG. 4 is a flow diagram describing a process 400 for growing an oxide layer on a substrate in accordance with an embodiment of the present invention. In action 402, a substrate is provided which can be any substrate, such as a silicon (Si) wafer, a quartz wafer, a quartz rod, and the like.

In action 404, a coating material is applied to the substrate using, for example, a low temperature chemical vapor deposition process. The coating materials can be applied using other methods, such as dipping, spraying, spray and spin and the like. The coating materials can include, for example, various combinations of H₂, SiH₄, Si₂H₆ and O₂ and SOG.

For purposes of illustration, with no intent to limit the invention, a spin coating can be used to apply the coating materials. A conventional spin coating technique typically involves preparing a fluid consisting of the coating material dissolved, dispersed, or suspended in a suitable volatile solvent or other vehicle, along with any other process or product enhancing additive; dispensing an amount of the fluid on the substrate, and spinning the substrate with a rotational speed sufficient to spread the coating fluid in a uniform thickness over at least the portion of the substrate intended to be coated. The rotational speed, surface tension, and viscosity of the coating fluid generally determine the thickness of the resulting coating.

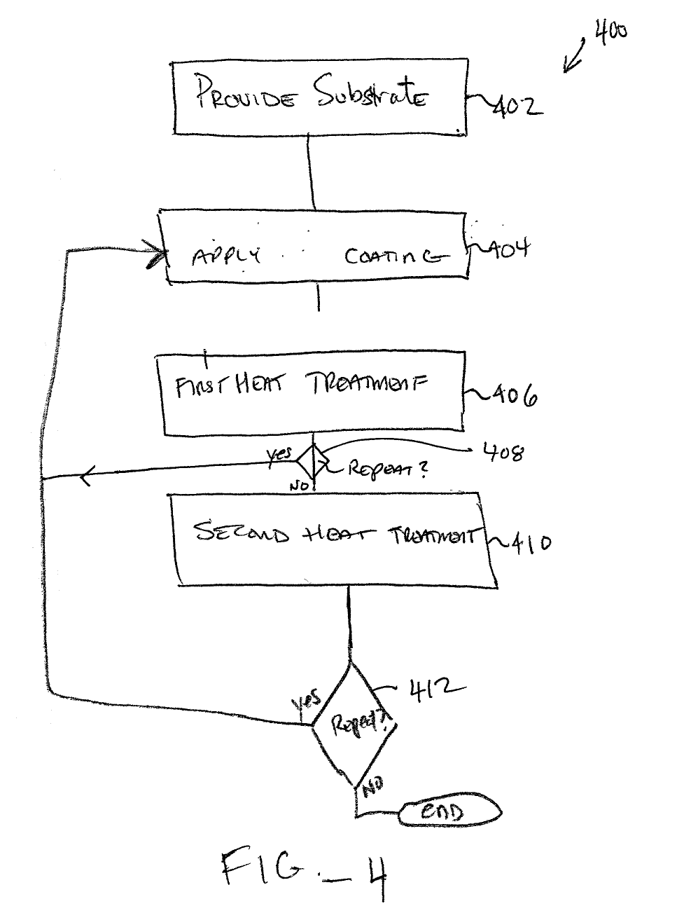

FIG. 5 is a simplified cross-sectional view of a coated Si wafer 502 with coating material 504 on Si wafer 506, which results from the spin coating, dipping process or other deposition process as in accordance with embodiments of the present invention. For purposes of illustration, with no intent to limit the invention, in one embodiment, coating material 504 can be a layer of SOG, which is a mixture of SiO₂ and dopants, such as boron and phosphorous, that is suspended or desorbed in a solvent solution.

Referring again to FIG. 4, in action 404 coating material 504 can be layered on wafer 506 to any desired thickness, for example, a thickness of between about 1000 Å and about 5000 Å.

In action 406, coated substrate 502 is further processed in a rapid thermal processor. The processing includes heat treatment of coated wafer 502. Any suitable rapid thermal processor can be used to process coated wafer 502. For example, referring to FIGS. 1C and 1D, reactor 100 may be any type of reactor which allows wafers to be loaded at wafer processing temperatures, of between about 100° C. to about 1300° C., without adverse results.

In action 406, a first heat treatment bakes coated wafer 502 at a temperature of between about 200° C. and about 400° C. The first heat treatment in action 406 can be maintained until the solvent, water and alcohol, which are typically present in coating material 504 are outgassed. In one embodiment, when coating material 504 includes SOG, the time duration of the first heat treatment can be maintained, for example, between about 5 minutes to about 10 minutes to complete the outgassing.

In some embodiments, in order to grow the oxide layer to a desired thickness, the process can return at action 408 to action 404 such that additional layers of between 1000 Å and 5000 Å of coating material 504 can be added to the previously baked layer. Actions 404 and 406 of process 400 can repeat until a desired thickness of a baked material is formed. For example, actions 404 and 406 can be repeated until the baked layer is between about 0.5 μm and 20 μm. In these embodiments, after each additional layer of coating material 504 is added, the wafer can again be subjected to the first heat treatment (Action 406).

Once a desired thickness of coating material 504 is formed or as desired, the process continues with a second heat treatment. In action 410, the second heat treatment is a hardening or curing process conducted at temperatures of between about 800° C. and about 1300° C. The second heat treatment of action 410 can be maintained until the refractive index of the outgassed coating material matches a preselected refractive index, for example, a refractive index of about 1.4. In the embodiment on which coating material 504 is SOG, the curing treatment can be maintained, for example, between about 5 minutes to about 10 minutes. Alternatively, the second heat treatment can be deemed complete when film shrinkage, which can occur during the second heat treatment, has substantially stopped.

Thereafter, process 400 can again be repeated at action 412, if necessary or desired, to action 404 with another layering of coating material 504 being disposed on top of the previously cured layer.

Single wafer processing of a coated substrate as described is advantageous in that the processing is not diffusion limited nor is the Si wafer substantially consumed in the process.

Having thus described embodiments of the present invention, persons skilled in the art will recognize that changes may be made in form and detail without departing from the scope of the invention. Thus the invention is limited only by the following claims.

What is claimed is:

1. A method for forming an oxide layer comprising:
(a) applying a coating material to a substrate;
(b) heating said first layer to a first process temperature for a first time duration to form a first processed layer; and
(c) heating said first processed layer to a second process temperature for a second time duration to form a second processed layer.

2. The method of claim 1, further comprising:
applying a second layer of said coating material over said second processed layer;
heating said second layer of said coating material to said first process temperature for said first time duration to form a third processed layer; and
heating said third processed layer to said second process temperature for said second time duration to form a fourth processed layer.

3. The method of claim 1, wherein said thickness of said second processed layer is between about 1,000 Å and 1 μm.

4. The method of claim 1, wherein said first time duration is between about five minutes to about ten minutes; and
wherein said second time duration is between about five minutes to about ten minutes.

5. The method of claim 1, wherein said first process temperature is between about 200° C. and about 400° C.

6. The method of claim 1, wherein said second process temperature is up to about 1300° C.

7. The method of claim 1, wherein said coating material comprises spin-on glass (SOG).

8. The method of claim 7, wherein said heating to said first process temperature causes said SOG to outgas to form a layer of SiO₂; and
wherein said second process temperature causes said layer of SiO₂ to cure.

9. The method of claim 7, wherein said applying a coating material comprises applying a layer of spin-on glass to a substrate.

10. The method of claim 1, wherein said substrate comprises a quartz substrate.

11. The method of claim 1, further comprising repeating (a), (b), and (c) until an oxide layer of a pre-selected thickness is formed.

12. A method for forming an oxide layer on a substrate comprising:
(a) applying a first layer of a spin-on glass (“SOG”) to a substrate;
(b) heating said first layer to a first process temperature for a first time duration to cause said first layer of SOG to outgas to form a layer of SiO₂; and
(c) heating said layer of SiO₂ to a second process temperature for a second time duration to cause said SiO₂ layer to harden.

13. The method of claim 12, further comprising:
applying a second layer of SOG over said layer of SiO₂;
heating said second layer of SOG to said first process temperature for said first time duration; and
heating said second layer of SOG to said second process temperature for said second time duration.

14. The method of claim 12, wherein said thickness of said SiO₂ layer is between about 1,000 Å and 1 μm.

15. The method of claim 12, wherein said first time duration is between about five minutes to about ten minutes; and
wherein said second time duration is between about five minutes to about ten minutes.

16. The method of claim 12, wherein said first process temperature is between about 200° C. and about 400° C.

17. The method of claim 12, wherein said second process temperature is up to about 1300° C.

18. The method of claim 12, wherein said substrate comprises a quartz substrate.

19. The method of claim 12, wherein said applying a first layer of SOG to a substrate comprises dipping said substrate in a bath of said SOG.

20. The method of claim 12, further comprising repeating (a), (b), and (c) until an SiO₂ layer of a pre-selected thickness is formed.

21. An apparatus for forming an oxide film on a semi-conductor substrate comprising:
means for applying a first layer of a spin-on glass (“SOG”) to a substrate;
means for heating said first layer to a first process temperature for a first time duration to cause said first layer of SOG to outgas to form a layer of SiO₂; and
means for heating said SiO₂ layer to a second process temperature for a second time duration to cause said SiO₂ layer to harden.

22. An apparatus for forming an oxide film on a substrate comprising:
a processing chamber defining a cavity configured to receive a substrate; and
a burner assembly disposed in said cavity configured to provide a plurality of flames fueled by process gases emanating from a first surface of said burner assembly, said flames directed perpendicular to said substrate.

23. The apparatus of claim 22, wherein said substrate comprises a silicon wafer.

24. The apparatus of claim 22, wherein said burner assembly comprises a plurality of nozzles configured in an array on said first surface of said burner assembly.

25. The apparatus of claim 22 wherein said process gases comprise a mixture of H₂ and O₂.

26. The apparatus of claim 22, wherein said burner assembly comprises a first plurality of nozzles and a second plurality of nozzles, wherein a first process gas emanates from said first plurality of nozzles and a second process gas emanates from said second plurality of nozzles.

27. The apparatus of claim 26, wherein said first process gas comprises H₂ and said second process gas comprises O₂.

28. An method for forming an oxide film on a substrate comprising:
providing a substrate; and
heating said substrate using a plurality of process flames fueled with H₂ and O₂ and directed perpendicular to a first surface of said substrate, said plurality of process flames causing a formation of H₂O vapor and oxygen radicals, said H₂O vapor and said oxygen radicals used alone or in combination as reactant to form an oxidation layer on a first surface of said substrate.

29. The method of claim 28, wherein said heating is accomplished using a burner assembly, said plurality of process flames emanating from a first surface of said burner assembly.

30. The method of claim 29, wherein said burner assembly comprises an array of nozzles, wherein said H₂ and O₂ emanate from each of said nozzles.

31. The method of claim 29, wherein said burner assembly comprises a first plurality of nozzles from which said H₂ is provided and a second plurality of nozzles from which said O₂ is provided.
